(19) United States
(12) Patent Application Publication
(10) Pub. No.: US 2025/0379129 A1
(43) Pub. Date: Dec. 11, 2025

(54) CONDUCTIVE STRUCTURE AND INTERCONNECTS FOR ELECTRICALLY CONNECTING A SUBSTRATE AND AN INTERPOSER

(71) Applicant: QUALCOMM Incorporated, San Diego, CA (US)

(72) Inventors: Aniket PATIL, San Diego, CA (US); Zhijie WANG, San Diego, CA (US); Joan Rey Villarba BUOT, Escondido, CA (US)

(21) Appl. No.: 18/734,866

(22) Filed: Jun. 5, 2024

(51) Int. Cl. H01L 23/498; H01L 23/00; H01L 23/31; H01L 25/16; H10B 80/00

(52) U.S. Cl. CPC H01L 23/49811; H01L 23/49861; H01L 25/162; H10B 80/00; H01L 23/3107; H01L 24/16; H01L 2224/16225

(57) ABSTRACT

A device includes a substrate, an interposer, a die disposed between the substrate and the interposer, and a conductive structure disposed between the substrate and the interposer. The conductive structure includes one or more walls defining one or more openings. The one or more walls are electrically connected to the substrate via a first plurality of terminals and to the interposer via a second plurality of terminals. The device further includes a plurality of interconnects disposed within the one or more openings and electrically isolated from the conductive structure. The plurality of interconnects electrically connect the substrate and the interposer.

### FIELD

Various features relate to conductive structures and interconnects for electrically connecting substrates and interposers.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art mobile application devices demand a small form factor, low cost, a tight power budget, and high electrical performance. One challenge associated with mobile package design is maintaining the small form factor as technology improves and the number of interconnections between devices increases. To illustrate, as integrated circuits become more complicated and as larger numbers of integrated circuit devices are interconnected, interconnects for signal paths between various devices take up a substantial amount of space on substrates within semiconductor packages. These interconnects may be for the propagation of data signals or to provide common source signals or common net signals, such as power and ground. For example, interconnects for a common ground can be up to 30% of the interconnects on a particular level of a semiconductor package. This large number of interconnects reduces the space available for other components within the semiconductor package or for other signal paths, which can reduce the amount of components in a semiconductor package or increase the difficulty and complexity of semiconductor package design and signal routing.

### SUMMARY

Various features relate to integrated circuit devices.

One example provides a device that includes a substrate. The device also includes an interposer. The device includes a die disposed between the substrate and the interposer. The device also includes a conductive structure disposed between the substrate and the interposer. The conductive structure includes one or more walls defining one or more openings. The one or more walls are electrically connected to the substrate via a first plurality of terminals and to the interposer via a second plurality of terminals. The device further includes a plurality of interconnects disposed within the one or more openings and electrically isolated from the conductive structure. The plurality of interconnects electrically connect the substrate and the interposer.

Another example provides a method of semiconductor fabrication that includes electrically connecting a first plurality of terminals of a conductive structure to a substrate. The conductive structure includes one or more walls defining one or more openings. The method also includes electrically connecting a plurality of interconnects within the one or more openings to the substrate. The plurality of interconnects are electrically isolated from the conductive structure. The method further includes electrically connecting an interposer to a second plurality of terminals of the conductive structure and to the plurality of interconnects, the one or more walls electrically connected to the substrate via the first plurality of terminals and to the interposer via the second plurality of terminals.

Another example provides a device that includes a conductive structure configured to provide common voltage interconnections between a substrate and an interposer. The conductive structure includes one or more walls defining one or more openings configured to receive a plurality of interconnects between the substrate and the interposer. The one or more walls are electrically isolated from the plurality of interconnects. The conductive structure also includes a first plurality of terminals configured to provide electrical interconnections to the substrate. The conductive structure further includes a second plurality of terminals configured to provide electrical interconnections to the interposer.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1A illustrates a top view of an exemplary device that includes a conductive structure and interconnects configured to electrically connect a substrate and an interposer.

FIG. 1B illustrates a cross-sectional profile view of the exemplary device of FIG. 1A.

FIG. 1C illustrates a three-dimensional (3D) isometric view of a portion of the exemplary conductive structure and interconnects of FIGS. 1A-B.

FIG. 2 illustrates a top view of an exemplary device that includes multiple isolated conductive structures and interconnects configured to electrically connect a substrate and an interposer.

FIG. 3A illustrates a first part of an exemplary sequence for fabricating an exemplary device that includes a conductive structure and interconnects configured to electrically connect a substrate and an interposer.

FIG. 3B illustrates a second part of an exemplary sequence for fabricating an exemplary device that includes a conductive structure and interconnects configured to electrically connect a substrate and an interposer.

FIG. 3C illustrates a third part of an exemplary sequence for fabricating an exemplary device that includes a conductive structure and interconnects configured to electrically connect a substrate and an interposer.

FIG. 3D illustrates a fourth part of an exemplary sequence for fabricating an exemplary device that includes a conductive structure and interconnects configured to electrically connect a substrate and an interposer.

FIG. 4 illustrates an exemplary flow diagram of a method of semiconductor fabrication for a device that includes a conductive structure and interconnects configured to electrically connect a substrate and an interposer.

FIG. 5 illustrates various electronic devices that may integrate an exemplary conductive structure and interconnects described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices has led to increasing complexity of ICs. Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an integrated circuit (IC). The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

State-of-the-art mobile application devices demand a small form factor, low cost, a tight power budget, and high electrical performance. Mobile package design has evolved to meet these divergent goals for enabling mobile applications that support multimedia enhancements. For example, fan-out (FO) wafer level packaging (WLP) or FO-WLP process technology is a development in packaging technology that is useful for mobile applications. This chip first FO-WLP process technology solution provides flexibility to fan-in and fan-out connections from a die to package balls. In addition, this solution also provides a height reduction of a first level interconnect between the die and the package balls of mobile application devices. These mobile applications, however, are susceptible to power and signal routing issues when multiple dies are arranged within the small form factor.

Stacked die schemes and chiplet architectures are becoming more common as significant power performance area (PPA) yield enhancements are demonstrated for stacked die and chiplet architecture product lines. As used herein, “stacked dies” and/or “stacked ICs” refer to arrangements in which one die (e.g., a first die) is disposed over (including directly over) another die (e.g., a second die). Unfortunately, stacked die schemes and other state-of-the-art IC designs can result in increased number of interconnects between IC devices, particularly between substrates and interposers in semiconductor packages, which can reduce the available area for other components and increase difficulty of semiconductor package design and layout. Various aspects of the present disclosure provide conductive structure(s) and interconnects for connecting substrates and interposers that occupy reduced area within semiconductor package(s) as compared to other semiconductor package designs.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

A 3D integrated circuit (3D IC) includes a set of stacked and interconnected dies. Generally, a 3D IC architecture can achieve higher performance, increased functionality, lower power consumption, and/or smaller footprint, as compared to providing the same circuitry in a monolithic die or in a two-dimensional (2D) IC structure. Unfortunately, routing signals among 3D ICs may use a significant quantity of interconnects between layers. As an illustrative example, a substrate acting as one layer of a 3D IC may include a die and two groups of interconnects, with each group having multiple rows and four columns of interconnects, which is as much as a 30% increase from a previous generation 3D IC in which the substrate included the same number of rows and only three columns of interconnects. These additional interconnects reduce the available space that can be used for other components and add additional difficulty and complexity to signal routing and layout.

Aspects of the present disclosure are directed to a conductive structure and interconnects for connecting a substrate and an interposer within a semiconductor package. In some aspects, a die and a conductive structure are disposed between a substrate and an interposer. The conductive structure includes walls that define openings, and these walls are electrically connected to the substrate via first terminals and to the interposers via second terminals. Interconnects may be disposed in the openings defined by the walls and may be electrically isolated from the conductive structure (e.g., the walls) to electrically connect the substrate and the interposer, such as to common signal sources such as power and ground. The disclosed conductive structure with the interconnects disposed within the openings provides electrical connections between the substrate and the interposer and occupies less space on the substrate than adding additional interconnects to provide the same electrical connections, as in other semiconductor packages that include more interconnects and thus have less available space on a respective substrate.

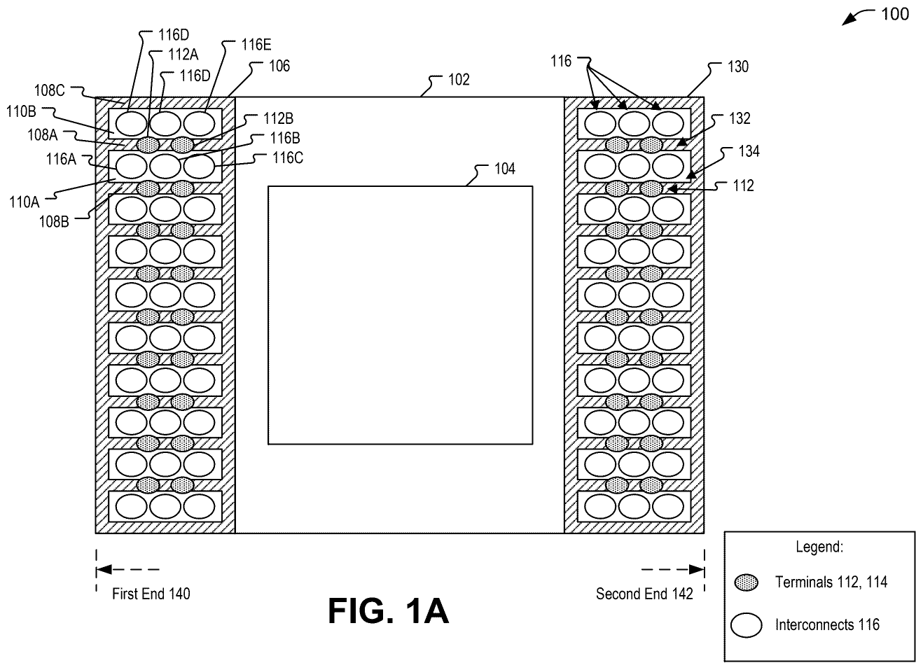

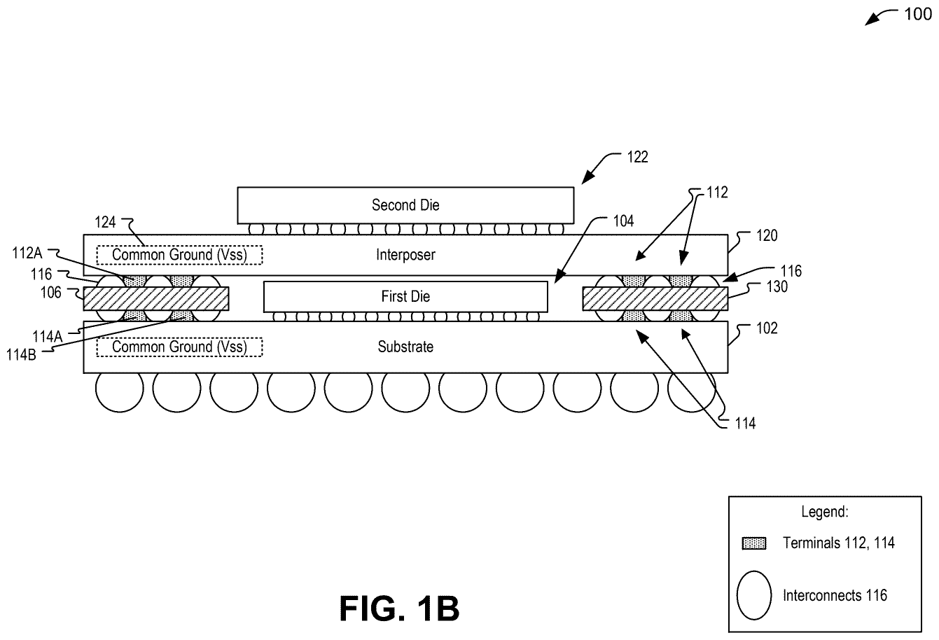

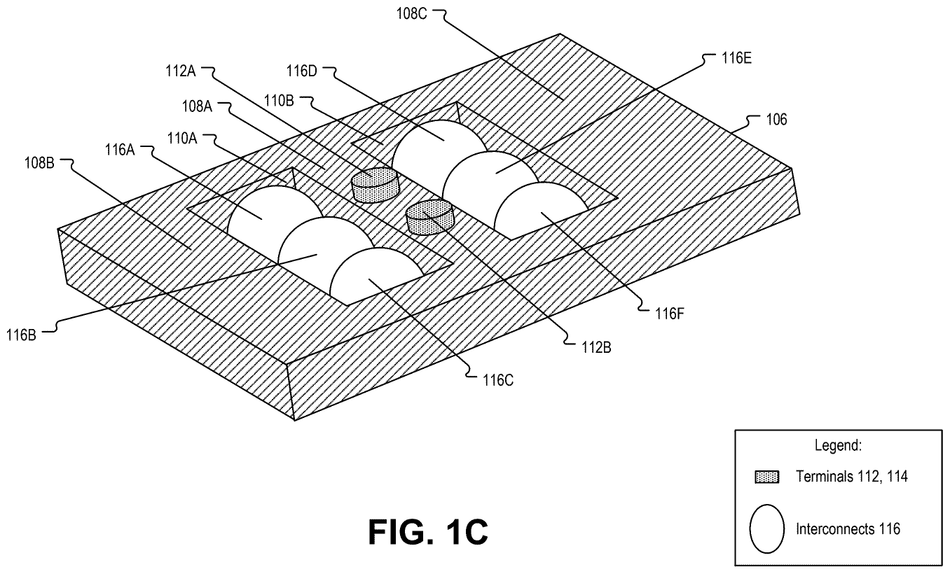

In some drawings, multiple instances of a particular type of feature are used. Although these features are physically and/or logically distinct, the same reference number is used for each, and the different instances are distinguished by addition of a letter to the reference number. When the features as a group or a type are referred to herein e.g., when no particular one of the features is being referenced, the reference number is used without a distinguishing letter. However, when one particular feature of multiple features of the same type is referred to herein, the reference number is used with the distinguishing letter. For example, referring to FIG. 1A, multiple walls are illustrated and associated with reference numbers 108A and 108B. When referring to a particular one of these walls, such as a wall 108A, the distinguishing letter “A” is used. However, when referring to any arbitrary one of these walls or to these walls as a group, the reference number 108 is used without a distinguishing letter.

### Exemplary Device Including a Conductive Structure and Interconnects

FIG. 1A illustrates a top view of an exemplary device 100 that includes a conductive structure and interconnects configured to electrically connect a substrate and an interposer. FIG. 1B illustrates a cross-sectional profile view of the exemplary device 100 of FIG. 1A. FIG. 1C illustrates a three-dimensional (3D) isometric view of a portion of the exemplary conductive structure and interconnects of FIGS. 1A-B.

In the implementation shown in FIGS. 1A-B, the device 100 includes a substrate 102, a first die 104 that is electrically connected to the substrate 102, a conductive structure 106, a conductive structure 130, an interposer 120 (not shown in FIG. 1A), and a second die 122 (not shown in FIG. 1A) that is electrically connected to the interposer 120. The first die 104, the conductive structure 106, and the conductive structure 130 may be disposed between the substrate 102 and the interposer 120. In aspects, the first die 104, the conductive structure 106, and the conductive structure 130 are disposed on the same surface (e.g., a top surface) of the substrate 102, and the conductive structure 106 and the conductive structure 130 may be disposed at opposite ends (e.g., sides) of the substrate 102. For example, the conductive structure 106 may be disposed at a first end 140 of the substrate 102 and to a first side of the first die 104, and the conductive structure 130 may be disposed at a second end 142 of the substrate 102 that is opposite to the first end 140 and to a second side of the first die 104 that is opposite to the first side.

Each of the first die 104 and the second die 122 can include integrated circuitry, such as a plurality of transistors and/or other circuit elements arranged and interconnected to form logic cells, memory cells, etc. Components of the integrated circuitry can be formed in and/or over a semiconductor substrate, such as integrated substrates of the first die 104 or the second die 122, or the substrate 102 or the interposer 120. Different implementations can use different types of transistors, such as a field effect transistor (FET), planar FET, finFET, a gate all around FET, or mixtures of transistor types. In some implementations, a front end-of-line (FEOL) process may be used to fabricate the integrated circuitry in and/or over the individual semiconductor substrates, the substrate 102, the interposer 120, or a combination thereof.

The first die 104 and the second die 122 may include or correspond to chiplets or other IC devices that can be arranged and interconnected as a three-dimensional (3D) IC device. In some implementations, the first die 104, the second die 122, or both, include one or more microcontrollers, application specific integrated circuits (ASICs), field programmable gate arrays (FPGAs), central processing units (CPUs) having one or more processing cores, processing systems, system on chip (SoC), or other circuitry and logic configured to facilitate the operations of the first die 104, the second die 122, or both. Additionally, or alternatively, the first die 104, the second die 122, or both, may include or be operated as a memory, such as a static random-access memory (SRAM), a dynamic random-access memory (DRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof. In a particular implementation, the second die 122 includes or corresponds to a DRAM.

In some implementations, the IC devices (e.g., the first die 104 and the second die 122) are electrically connected to, or integrated with, respective substrates. For example, the first die 104 may be electrically connected (e.g., via one or more contacts or interconnects) to the substrate 102. As another example, the second die 122 may be electrically connected (e.g., via one or more contacts or interconnects) to the interposer 120. Any of the conductive interconnects and contacts described herein between the first die 104 and the substrate 102, or between the second die 122 and the interposer 120, can include, for example, microbumps, conductive pillars, conductive pads (e.g., for pad to pad bonding), or other chip-to-substrate interconnect contacts. Although described herein as being electrically connected to a single IC device, in other implementations, either or both of the substrate 102 and the interposer 120 may be electrically connected to multiple IC devices. For example, the device 100 may include the first die 104 and one or more additional dies that are electrically connected to the substrate 102. As another example, the device 100 may include the second die 122 and one or more other dies that are electrically connected to the interposer 120. In some implementations, one or more IC devices may be interconnected through a respective substrate by one or more conductive pathways, which can include one or more metal structures formed from metal layers of the respective substrate, one or more vias or other inter-level connections, other routings or interconnects, or a combination thereof. Additionally, or alternatively, the device 100 may include one or more components or other structures (e.g., landside capacitors) on an opposite surface of the substrate 102 from the first die 104, and the conductive pathways within the substrate 102 may provide electrical connections between the first die 104 and the components or other structures on the opposite surface of the substrate 102.

Although not shown in FIGS. 1A-B, the device 100 may also include a mold compound disposed between the substrate 102 and the interposer 120, and optionally on or around the second die 122, such that the mold compound at least partially surrounds or encapsulates the first die 104, the conductive structure 106, and the conductive structure 130 (and optionally the second die 122). The mold compound may be any mold compound that is electrically stable at high temperatures and may be deposited on the first die 104, the conductive structure 106, and the conductive structure 106 to define at least part of a package (e.g., a semiconductor package, such as a mobile package) that includes the substrate 102, the first die 104, the conductive structures 106, 130, the interposer 120, and the second die 122.

The conductive structure 106 is configured to provide common voltage interconnections between the substrate 102 and the interposer 120. In aspects, the conductive structure 106 is disposed between the substrate 102 and the interposer 120 and electrically connects (e.g., provides a conductive path between) one or more conductors within or on a top surface of the substrate 102 and one or more conductors within or on a bottom surface of the interposer 120. The conductive structure 106 may be formed from or include an electrically conductive material, such as a metal, a metal alloy, or another electrically conductive material, and the conductive structure 106 may have a dielectric coating. As non-limiting examples, the conductive structure 106 may include copper, aluminum, or alloys thereof, that are coated by a dielectric material. In some implementations, the conductive structure 106 is a copper mesh block. The dielectric coating of the conductive structure 106 insulates the interior conductive material from coming into direct contact with adjacent components and prevents the conductive structure 106 from being electrically connected to the substrate 102 or the interposer 120 other than by terminals, as further described herein, as well as electrically isolating nearby interconnects from the walls of the conductive structure 106. The conductive structure 106 may include one or more walls 108 that define one or more openings 110, as further described herein, and the dielectric coating may cover each of the walls 108. In some other implementations, the conductive structure 106 does not include the dielectric coating, and any above-described electrical isolation may be provided by gaps between the conductive structure 106 and the respective other components.

In aspects, the conductive structure 106 is electrically connected to the substrate 102 via first terminals 114. The first terminals 114 may be configured to provide electrical interconnections between the conductive structure 106 and the substrate 102. In such aspects, the conductive structure 106 is also electrically connected to the interposer 120 via second terminals 112. The second terminals 112 may be configured to provide electrical interconnections between the conductive structure 106 and the interposer 120. For example, the first terminals 114 and the second terminals 112 may include metal or a metal alloy, such as copper, and may be disposed on opposite surfaces of the conductive structure 106 such that, when the first terminals 114 are coupled to the substrate 102 and the second terminals 112 are coupled to the interposer 120, one or more conductors within or on the bottom surface of the interposer 120 are electrically connected to one or more conductors within or on the top surface of the substrate 102 through the second terminals 112, the conductive structure 106, and the first terminals 114. The one or more conductors within or on the substrate 102, the interposer 120, or both, may be connected to (e.g., form a conductive path to) a common source signal or a common net signal, as further described herein. In some implementations, the first terminals 114 and the second terminals 112 are copper (or another metal or metal alloy) terminals that are in direct contact with the metal within the conductive structure 106 and with the conductors of the substrate 102 and the interposer 120, respectively, thereby creating the electrical connection (e.g., a conductive path) between the substrate 102 and the interposer 120. Although referred to as terminals, the first terminals 114, the second terminals 112, or both, may be pins or other types of interconnects. To electrically connect the first terminals 114 and the second terminals 112 to the conductive structure 106, openings in the dielectric coating of the conductive structure 106 may be formed to receive the terminals 112, 114, such as via a lithography process, an etching process, a grinding process, or the like.

A particular common net signal or common source signal may be electrically connected to the conductive structure 106 via the substrate 102 or the interposer 120. In some implementations, the conductive structure 106, the substrate 102, and the interposer 120 are electrically connected to a common net signal such as a common ground 124 (e.g., Vss). For example, the common ground 124 Vss may be applied to the interposer 120 (or the substrate 102) and may be provided along a conductive path from the bottom surface of the interposer 120 to the top surface of the substrate 102 across the second terminals 112, the conductive structure 106, and the first terminals 114 instead of using multiple discrete interconnects. Because the common ground 124 can be part of a return path for other signals, signal performance can be improved by distributing access to the common ground 124 across signal and power interconnect locations to provide shorter (e.g., better) return paths for the corresponding signals. In some other implementations, the conductive structure 106, the substrate 102, and the interposer 120 are electrically connected to a common source voltage (e.g., Vdd), that is applied to the interposer 120 (or the substrate 102) and may be provided along a conductive path from the interposer 120 to the substrate 102 across the second terminals 112, the conductive structure 106, and the first terminals 114.

The conductive structure 106 may include the walls 108 that define the openings 110 that are configured to receive interconnects 116 between the substrate 102 and the interposer 120. For example, the walls 108 may define the openings 110 arranged as a column along the first end 140 of the substrate 102, with each of the openings 110 enclosed by at least two of the walls 108 and configured to receive three of the interconnects 116 arranged in a row, as shown in FIG. 1A. In other implementations, the openings 110 may be arranged in more than one column or another arrangement, the openings 110 may be configured to receive fewer than three or more than three of the interconnects 116, which may be arranged in a single row or more than one row. Alternatively, the conductive structure 106 may be configured such that the walls 108 and the openings 110 have different shapes or arrangements than shown in FIG. 1A.

The interconnects 116 may be disposed within the openings 110 and be electrically isolated from the conductive structure 106 (e.g., from the walls 108). For example, one or more gaps may separate each of the interconnects 116 from physical contact with the walls 108 of the conductive structure 106. In some implementations, the spacing between at least some of the interconnects 116 and the walls 108 is between approximately 1 to 5 μm, which provides the gaps between the interconnects 116 and the walls 108. These gaps may prevent direct contact between, and therefore prevent electrical connection (e.g., provide electrical isolation) between the interconnects 116 and the conductive structure 106. Additionally, or alternatively, the interconnects 116 may be electrically isolated from the conductive structure 106 due to the dielectric coating covering the conductive structure 106. In aspects, the interconnects 116 are configured to electrically connect the substrate 102 and the interposer 120 and provide signal paths and/or voltage connections between one or more devices within, on, or coupled to the substrate 102 and the interposer 120.

In the implementation shown in FIGS. 1A-C, the interconnects 116 include multiple discrete interconnects that extend between the substrate 102 and the interposer 120. The interconnects 116 may include, for example, microbumps, conductive pillars, conductive pads (e.g., for pad-to-pad bonding), or other similar chiplet-to-chiplet interconnect contacts used for 3D chiplet stacking. As an illustrative example, interconnects 116 may include input/output pad (IOP) balls, such as solder balls or other metal or metal alloy structures and input/output (IO) pads, that provide an electrical connection between a region on the top surface of the substrate 102 to a region on the bottom surface of the interposer 120. In other examples, the interconnects 116 may include conductive pillars, microbumps, or other interconnecting structures. In aspects, the interconnects 116 are configured to provide signal paths for power or other signals that are near a respective return path provided by the conductive structure 106, which may be coupled to the common ground 124, as described above.

In the implementation shown in the expanded view of the conductive structure 106 in FIG. 1C, the interconnects 116 include multiple sets of interconnects 116 that are each disposed within a corresponding one of the openings 110. In this implementation, each of the openings 110 is separated from an adjacent opening 110 by one of the walls 108. The mesh block wall locations and terminal locations (e.g., the locations of the walls 108 and the terminals 112, 114 of the conductive structure 106) are well chosen, such as between rows of a 90-degree grid IOP array (e.g., the interconnects 116) of a conventional semiconductor package to minimize the size of the conductive structure 106 and thus maximize available area utilization within the semiconductor package.

To illustrate, a first wall 108A may separate a first opening 110A from a second opening 110B, a second wall 108B may separate the first opening 110A from an adjacent opening (or an edge of the conductive structure 106), and a third wall 108C may separate the second opening 110B from an adjacent opening (or another edge of the conductive structure 106). In this example, a first set of interconnects (e.g., including an interconnect 116A, an interconnect 116B, and an interconnect 116C) may be disposed within the first opening 110A and a second set of interconnects (e.g., including an interconnect 116D, an interconnect 116E, and an interconnect 116E) may be disposed within the second opening 110B. A first subset of the first terminals 114, which includes a first terminal 114A and a first terminal 114B, may be disposed on a bottom surface (e.g., a first surface) of the first wall 108A, as shown in FIG. 1B. Additionally, a second subset of the second terminals 112, which includes a second terminal 112A and a second terminal 112B, may be disposed on a top surface (e.g., a second surface) of the first wall 108A, with the second surface being opposite to the first surface, as shown in FIGS. 1A-C. Additional subsets of the first terminals 114 and the second terminals 112 may be disposed on the top and bottom surfaces of one or more of the walls 108B, 108C (not shown in FIG. 1C for ease of illustration). Thus, for each set of the interconnects 116, a return path to Vss (e.g., the common ground 124) may be provided by an adjacent one of the walls 108 of the conductive structure 106, which may be provided along a conductive path to the substrate 102 and the interposer 120 by one or more of the first terminals 114 and one or more of the second terminals 112 on the respective wall 108. Providing such a nearby return path for the signal paths through the interconnects 116 may reduce difficulty and complexity of signal routing and layout for the device 100, which may decrease fabrication cost and complexity associated with the device 100.

The conductive structure 106, including the terminals 112, 114, may be appropriately sized to fit between the substrate 102 and the interposer 120 and to at least partially surround, but remain electrically isolated from, the interconnects 116. In some implementations, each of the first terminals 114 have substantially the same height as others of the first terminals 114, each of the second terminals 112 have substantially the same height as others of the second terminals 112, and the conductive structure 106 has a uniform or substantially uniform height. In such implementations, a sum of a height of one of the first terminals 114, a height of one of the second terminals 112, and a height of the respective wall 108 that is disposed between the terminals is substantially equal to a height of one of the interconnects 116 that is in an opening 110 that is adjacent to the wall 108. Additionally, the sum of the heights and the interconnect height may both be substantially equal to a distance between the substrate 102 and the interposer 120. As such, utilizing the conductive structure 106 in the device 100 does not increase the height of the device 100.

Similar to the conductive structure 106, the conductive structure 130 is configured to provide common voltage interconnections between the substrate 102 and the interposer 120. In aspects, the conductive structure 130 is disposed between the substrate 102 and the interposer 120 and electrically connects (e.g., provides a conductive path between) one or more conductors within or on a top surface of the substrate 102 and one or more conductors within or on a bottom surface of the conductive structure 106. The conductive structure 130 may include one or more walls 132 that define one or more openings 134, similar to the walls 108 defining the openings 110. The walls 132 may be electrically connected to the substrate 102 via a third subset of the first terminals 114 and to the interposer 120 via a fourth subset of the second terminals 112. One or more of the interconnects 116 may be disposed within the openings 134 and electrically isolated from the conductive structure 130 (e.g., the walls 132), and these interconnects 116 may be electrically connected to one or more devices or components on, within, or coupled to the substrate 102 and/or the interposer 120 to provide a signal path between the device(s) or component(s), similar to the interconnects 116 within the openings 110 defined by the walls 108 of the conductive structure 106.

The conductive structure 106 may be connected to different portions of the substrate 102 and the interposer 120 than the conductive structure 130. To illustrate, the conductive structure 106 may be electrically coupled to a first set of conductors within or on the first portion of the substrate 102 and to a second set of conductors within or on the first portion of the interposer 120. Similarly, the conductive structure 130 may be electrically coupled to a third set of conductors within or on the second portion of the substrate 102 and a fourth set of conductors within or on the second portion of the interposer 120. The first set of conductors may be electrically connected to the third set of conductors and/or the second set of conductors may be electrically connected to the fourth set of conductors if the conductive structure 106 and the conductive structure 130 are to connected to the same common signal. Alternatively, the first set of conductors may be electrically isolated from the third set of conductors and the second set of conductors may be electrically isolated from the fourth set of conductors if the conductive structure 106 and the conductive structure 130 are to be connected to different common signals.

In some implementations, the different portions of the substrate 102 and the interposer 120 (e.g., the different sets of conductors) that are electrically connected by the conductive structures 106 and 130, respectively, are connected to different common net signals or common source signals. For example, the first set of conductors within or on the first portion of the substrate 102, the second set of conductors within or on the first portion of the interposer 120, and the conductive structure 106 may be electrically connected to the common ground 124, and the third set of conductors within or on the second portion of the substrate 102, the fourth set of conductors within or on the second portion of the interposer 120, and the conductive structure 130 may be electrically connected to Vdd or another power signal. As another example, the first set of conductors within or on the first portion of the substrate 102, the second set of conductors within or on the first portion of the interposer 120, and the conductive structure 106 may be electrically connected to Vdd or another power signal, and the third set of conductors within or on the second portion of the substrate 102, the fourth set of conductors within or on the second portion of the interposer 120, and the conductive structure 130 may be electrically connected to the common ground 124. Alternatively, the first and second portions of the substrate 102 (e.g., the respective conductors within or the portions of the substrate 102), the first and second portions of the interposer 120 (e.g., the respective conductors within or the portions of the interposer 120), and the conductive structures 106, 130 may be connected to the same common source signal or common net signal, such as the common ground 124 or Vdd.

It should be understood that the device 100 may include additional components, other components, fewer components, or a combination thereof, to support the functionality described herein. As non-limiting examples, the device 100 may include additional IC devices, additional layers, additional dies, additional packages, additional interconnects, additional structures, other components, different components, or a combination thereof, to support the functionality and technical advantages disclosed herein. Additionally, or alternatively, the arrangements of the conductive structures of the device 100 are not limiting and may be different in other implementations. For example, the device 100 may include a different number of the interconnects 116 than shown in FIGS. 1A-C, a different arrangement of the interconnects 116 (e.g., a different number of rows and/or columns of the interconnects 116, or a different shaped arrangement of the interconnects 116), a different type of interconnect (e.g., other than copper IOP balls), or multiple types of interconnects. As another example, the interconnects 116 may have different positions on the substrate 102 (e.g., relative to the first die 104), such as being positioned on a single side of the first die 104 (e.g., a single end of the substrate 102), being positioned along adjacent sides of the first die 104 (e.g., along adjacent ends of the substrate 102), being positioned along three sides of the first die 104 (e.g., along three ends of the substrate 102), or being positioned along four sides of the first die 104 (e.g., along four ends of the substrate 102). Additionally, or alternatively, the first terminals 114, the second terminals 112, or both, may include different numbers of terminals and/or a different arrangement of terminals than shown in FIGS. 1A-C. For example, each of the walls 108 may be coupled to a single terminal or more than two terminals of the first terminals 114, a single terminal or more than two terminals of the second terminals 112, or the terminals may be arranged further apart from adjacent terminals or closer to one edge of the walls 108 than another, as illustrative examples.

In some implementations, the device 100 can be integrated in a smartphone, a tablet computer, a fixed location terminal device, an automobile, a wearable electronic device, a laptop computer, or some combination thereof, as described in more detail below with reference to FIG. 6. In other examples, one or more additional integrated devices, packages, or some combination thereof can be present in a stacked integrated circuit without departing from the scope of the subject disclosure. Further, the conductive structure 106 and the interconnects 116 of FIGS. 1A-C can be integrated with or included within a wide variety of other devices. For example, a device that includes one or more of conductive structure 106 and the interconnects 116 of FIGS. 1A-C disclosed herein can include components such as a power management integrated circuit (PMIC), an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. In such devices, the first die 104, the second die 122, or both, of FIGS. 1A-C can operate as any of these components (or a combination of these components) that includes active circuitry.

The device 100 provides improved interconnections for common signals between a substrate and an interposer (e.g., another substrate) as compared to other semiconductor packages that include a die and a DRAM. In a conventional interconnection scheme, signal return paths use the same type of interconnects as those used to provided signal paths. For example, if signal paths are provided via copper core balls (as illustrated in the example of FIGS. 1A-C), signal return paths are conventionally provided by copper core balls. As a result, a large portion (e.g., around 30%) of the area used for interconnects in conventional interconnect schemes corresponds to signal returns path interconnects. In contrast, the conductive structures 106, 130 are able to provide the signal return paths using a much smaller area, thereby enabling a reduction to the size of the device 100, an increase in the number of IO interconnects that can be used for data signals (which can improve performance of the device 100), or both. Additionally, or alternatively, the conductive structures 106, 130 provide more paths to the common net signal or common source signal, and these paths may be located closer to the signal paths provided by the interconnects 116, thereby reducing the distance between these signal paths and a return path through Vss or a path from a common power signal, which can reduce the complexity of signal routing and strengthen the integrity of the signals propagated through the device 100. A technical advantage of the arrangement of the conductive structures 106, 130 and the interconnects 116 thus includes improved signal integrity (SI) and power integrity (PI) in a semiconductor package that has reduced size and cost compared to other similar semiconductor devices. Alternatively, the device 100 may include more components (due to the increased available area on the substrate 102) than other similar semiconductor devices with discrete interconnects for signal return paths. Another technical advantage of the arrangement of the conductive structures 106, 130 is that the placement of the conductive structures 106, 130 along the ends 140, 142 of the substrate 102 may reduce or prevent warping of the substrate 102 at the ends 140, 142, as compared to substrates that use a conventional interconnection scheme.

In a particular implementation, the device 100 includes a substrate (e.g., the substrate 102), an interposer (e.g., the interposer 120), and a die (e.g., the first die 104) that is disposed between the substrate and the interposer. The device 100 also includes a conductive structure (e.g., the conductive structure 106) that is disposed between the substrate and the interposer. The conductive structure includes one or more walls (e.g., the walls 108) that define one or more openings (e.g., the openings 110). The one or more walls are electrically connected to the substrate via a first plurality of terminals (e.g., the first terminals 114) and to the interposer via a second plurality of terminals (e.g., the second terminals 112). The device 100 further includes a plurality of interconnects (e.g., the interconnects 116) that are disposed within the one or more openings and electrically isolated from the conductive structure. The plurality of interconnects electrically connect the substrate and the interposer.

In a particular implementation, the device 100 includes a conductive structure (e.g., the conductive structure 106) configured to provide common voltage interconnections between a substrate (e.g., the substrate 102) and an interposer (e.g., the interposer 120). The conductive structure includes one or more walls (e.g., the walls 108) that define one or more openings (e.g., the openings 110) that are configured to receive a plurality of interconnects (e.g., the interconnects 116) between the substrate and the interposer. The one or more walls are electrically isolated from the plurality of interconnects. The conductive structure also includes a first plurality of terminals (e.g., the first terminals 114) that are configured to provide electrical interconnections to the substrate. The conductive structure further includes a second plurality of terminals (e.g., the second terminals 112) that are configured to provide electrical interconnections to the interposer.

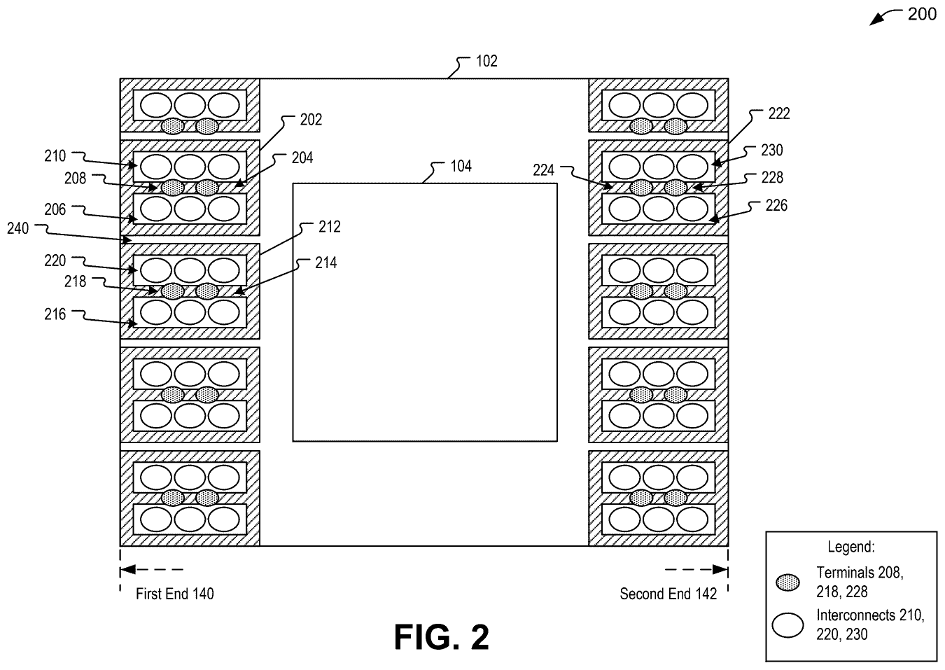

FIG. 2 illustrates a top view of an exemplary device 200 that includes multiple isolated conductive structures and interconnects configured to electrically connect a substrate and an interposer. The device 200 of FIG. 2 includes many of the same components and features as are described above with reference to FIGS. 1A-C. Such components and features are physically and operationally the same as described above with reference to FIGS. 1A-C and are labeled in FIG. 2 using the same reference numbers. In some implementations, the device 200 includes most of the same features and components as the device 100 of FIGS. 1A-C; however, some components and features illustrated in FIGS. 1A-C have been omitted from (or are not labeled with reference numbers in) FIG. 2 for simplicity of illustration and to highlight differences between the device 100 and the device 200. Omission of such features and reference numbers should not be understood as limiting the features and components of FIG. 2 to only those specifically called out below. For example, while FIG. 2 does not show the interposer 120 or the second die 122 of FIG. 1B, the device 200 can include the interposer 120 and the second die 122 (e.g., in a different view). To further illustrate, the interposer 120 may be disposed above the substrate 102, and the first die 104 may be disposed between the substrate 102 and the interposer 120, as shown in FIG. 1B.

Unlike the device 100 of FIGS. 1A-C, the device 200 of FIG. 2 includes multiple discrete conductive structures on one or more ends of the substrate 102. To illustrate, the device 200 may include illustrative conductive structures 202 and 212 disposed on the first end 140 of the substrate 102 (e.g., on a first side of the first die 104), and an illustrative conductive structure 222 disposed on the second end 142 of the substrate 102 (e.g., on a second side of the first die 104). Although three discrete conductive structures 202, 212, and 222 are described below, this description is for illustrative purposes and is not limiting. For example, the device 200 may include a single conductive structure or multiple conductive structures disposed on the first end 140 and a single conductive structure or multiple discrete conductive structures disposed on the second end 142.

In aspects, the conductive structures 202, 212, and 222 are disposed between the substrate 102 and the interposer 120 and electrically connect respective portions of the top surface of the substrate 102 and respective portions of the bottom surface of the conductive structure 106. For example, each of the conductive structures 202, 212, and 222 may be electrically connected to one or more conductors within or on the respective portions of the substrate 102 and the interposer 120, similar to as described above with reference to FIGS. 1A-C. Each of the conductive structures 202, 212, and 222 may at least partially surround one or more interconnects, such as one or more rows of interconnects, similar to as described above for the conductive structures 106, 130 of FIGS. 1A-C. Additionally, each of the conductive structures 202, 212, and 222 may be separate from and electrically isolated from any adjacent conductive structures.

The conductive structures 202, 212, and 222 may include one or more walls that define openings in which interconnects are disposed, similar to as described with reference to FIGS. 1A-C. To illustrate, the conductive structure 202 may include one or more walls 204 that define one or more openings 206. The walls 204 may be electrically connected to the substrate 102 via first terminals (not shown) and to the interposer 120 via second terminals 208. The first terminals may be disposed on a bottom surface of one or more of the walls 204, and the second terminals 208 may be disposed on a top surface of one or more of the walls 204. One or more interconnects 210 may be disposed within the openings 206 and electrically isolated from the conductive structure 202 (e.g., the walls 204), and the interconnects 210 may electrically connect one or more devices or components within, on, or coupled to the substrate 102 and one or more devices or components within, on, or coupled to the interposer 120. In some implementations, the conductive structure 202 is adjacent to one or more other conductive structures, such as the conductive structure 212, and a gap 240 may be located between the conductive structures 202, 212 to electrically isolate the conductive structure 202 from the conductive structure 212. The conductive structure 202 may also be electrically isolated from the conductive structure 212 due to both conductive structures 202, 212 having a dielectric coating to insulate the conductive respective interiors and prevent direct contact with adjacent components.

In some implementations, one or more of the conductive structures 202, 212, and 222 include three walls that define two openings, and sets of three interconnects are disposed within each of the two openings. For example, as shown in FIG. 2, the walls 204 may include a first wall, a second wall that extends parallel to the first wall, and a third wall that extends parallel to the second wall. The first wall and the third wall may be outer walls of the conductive structure 202 and the second wall may be an inner wall of the conductive structure 202. The walls 204 may define a first one of the openings 206 that is between the first wall (e.g., the top exterior wall 204 of the conductive structure 202 in FIG. 2) and the second wall and a second one of the openings 206 that is between the second wall and the third wall (e.g., the bottom exterior wall 204 of the conductive structure 202 in FIG. 2). The first one of the openings 206 (e.g., the top opening within the conductive structure 202 in FIG. 2) may be configured to receive a first set of the interconnects 210, and the second one of the openings 206 (e.g., the bottom opening within the conductive structure 202 in FIG. 2) may be configured to receive a second set of the interconnects 210. In some implementations, each set of the interconnects 210 includes three interconnects. In other implementations, the sets of the interconnects 210 may include fewer than three or more than three interconnects.

The conductive structures 212, 222 are similarly arranged and configured as the conductive structure 202. For example, the conductive structure 212 may include one or more walls 214 that define one or more openings 216. The walls 214 may be electrically connected to one or more conductors within or on the substrate 102 via third terminals (not shown) and to one or more conductors within or on the interposer 120 via fourth terminals 218. The third terminals may be disposed on a bottom surface of one or more of the walls 214, and the fourth terminals 218 may be disposed on a top surface of one or more of the walls 214. One or more interconnects 220 may be disposed within the openings 216 and electrically isolated from the conductive structure 212, and the interconnects 220 may electrically connect one or more devices or components within, on, or coupled to the substrate 102 and one or more devices or components within, on, or coupled to the interposer 120. In some implementations, the conductive structure 212 is adjacent to one or more other conductive structures, such as the conductive structure 202. Similarly, the conductive structure 222 may include one or more walls 224 that define one or more openings 226. The walls 224 may be electrically connected to one or more conductors within or on the substrate 102 via fifth terminals (not shown) and to one or more conductors within or on the interposer 120 via sixth terminals 228. The fifth terminals may be disposed on a bottom surface of one or more of the walls 224, and the sixth terminals 228 may be disposed on a top surface of one or more of the walls 224. One or more interconnects 230 may be disposed within the openings 226 and electrically isolated from the conductive structure 222, and the interconnects 230 may electrically connect one or more devices or components within, on, or coupled to the substrate 102 and one or more devices or components within, on, or coupled to the interposer 120.

In some implementations, one or more of the conductive structures 202, 212, and 222 may be electrically connected to different common net signals or different common source signals. For example, the conductive structure 202, the circuitry (e.g., one or more conductors) within or on the first portion of the substrate 102, and the circuitry within or on the first portion of the interposer 120 may be electrically connected to the common ground 124 of FIG. 1B, and the conductive structure 212, the circuitry within or on the second portion of the substrate 102, and the circuitry within or on the second portion of the interposer 120 may be electrically connected to Vdd or another power signal. As another example, the conductive structure 202, the circuitry within or on the first portion of the substrate 102, and the circuitry within or on the first portion of the interposer 120 may be electrically connected to Vdd, and the conductive structure 212, the circuitry within or on the second portion of the substrate 102, and the circuitry within or on the second portion of the interposer 120 may be electrically connected to the common ground 124. Thus, adjacent conductive structures on a same end of the substrate 102 may be connected to a common net signal or a common source signal, which may provide shorter distances for return paths (if connected to common net signals) or other signal paths for signals propagated through the interconnects 210, 220.

Additionally, or alternatively, conductive structures disposed on one end of the substrate 102 may be electrically connected to the same or different signals than conductive structures disposed on an opposite end of the substrate 102. For example, the conductive structure 202, the circuitry within or on the first portion of the substrate 102, and the circuitry within or on the first portion of the interposer 120 may be electrically connected to the common ground 124, and the conductive structure 222, the circuitry within or on the third portion of the substrate 102, and the circuitry within or on the third portion of the interposer 120 may be electrically connected to a different signal, such as Vdd. As another example, the conductive structure 202, the circuitry within or on the first portion of the substrate 102, and the circuitry within or on the first portion of the interposer 120 may be electrically connected to Vdd, and the conductive structure 222, the circuitry within or on the third portion of the substrate 102, and the circuitry within or on the third portion of the interposer 120 may be electrically connected to the common ground 124. Because different conductive structures and connected circuitry in different regions may be electrically connected to different common source signals or common net signals, the device 200 may be associated with reduced complexity signal layout and design as compared to the device 100 of FIGS. 1A-C.

It should be understood that the device 200 may include additional components, other components, fewer components, or a combination thereof, to support the functionality described herein. As non-limiting examples, the device 100 may include additional IC devices, additional layers, additional dies, additional packages, additional interconnects, additional structures, other components, different components, or a combination thereof, to support the functionality and technical advantages disclosed herein. Additionally, or alternatively, similar to as described above with reference to the device 100 of FIGS. 1A-C, the number, arrangements, positions, and types of the conductive structures of the device 200 may be different in other implementations, such as for the second terminals 208, the interconnects 210, the fourth terminals 218, the interconnects 220, the sixth terminals 228, and the interconnects 230. Additionally, or alternatively, the positions, arrangement, and number of walls of the conductive structures 202, 212, and 222 may be different than shown in FIG. 2 in some other implementations.

Exemplary Sequence for Fabricating a Device Including a Conductive Structure and Interconnects

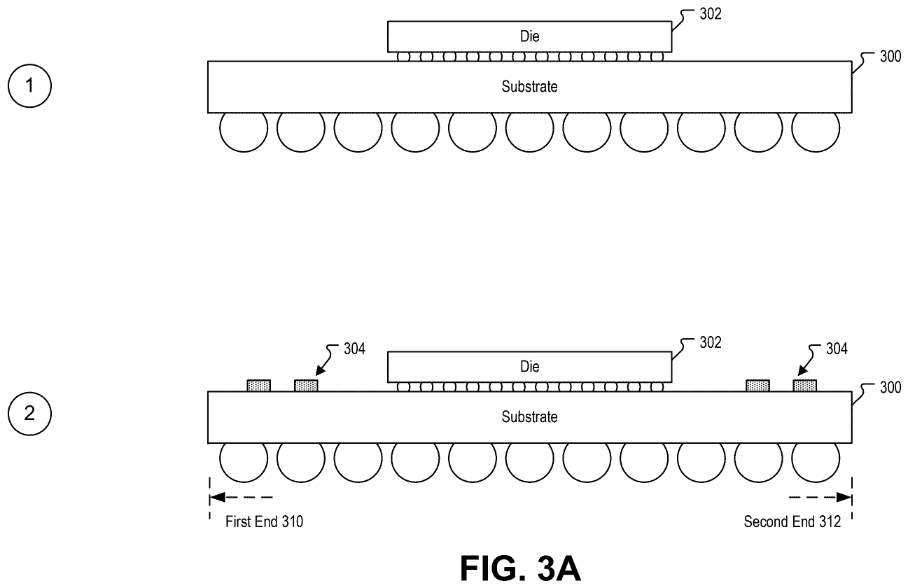

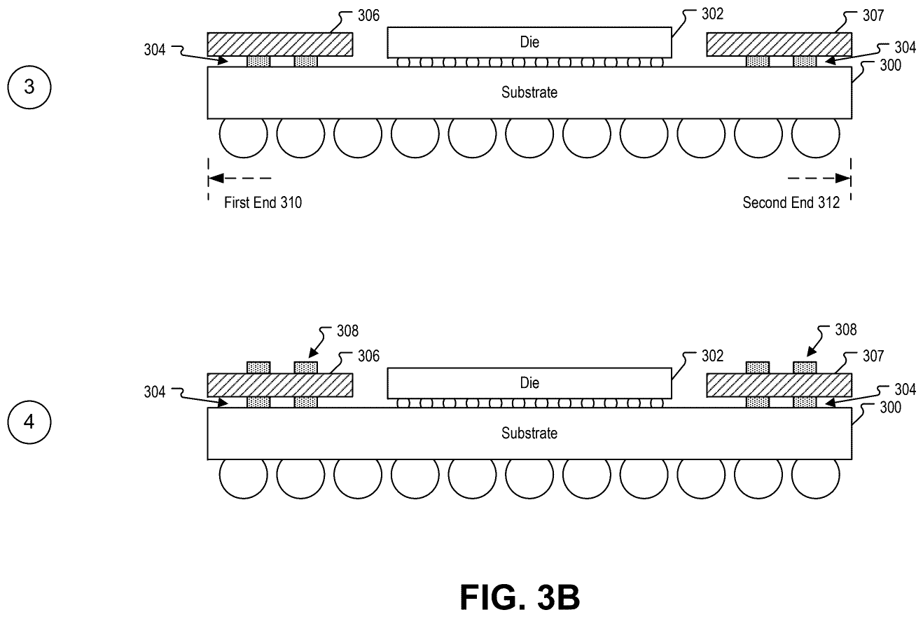

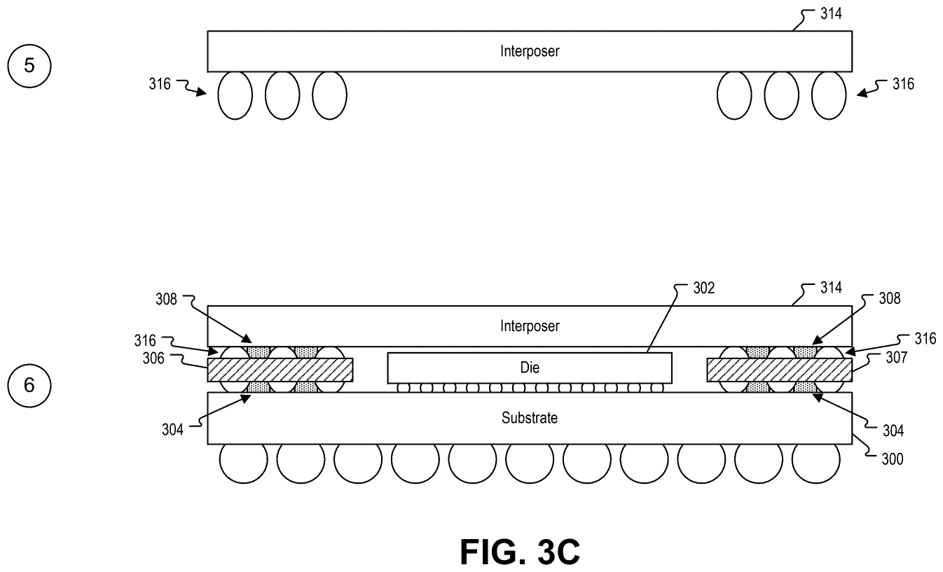

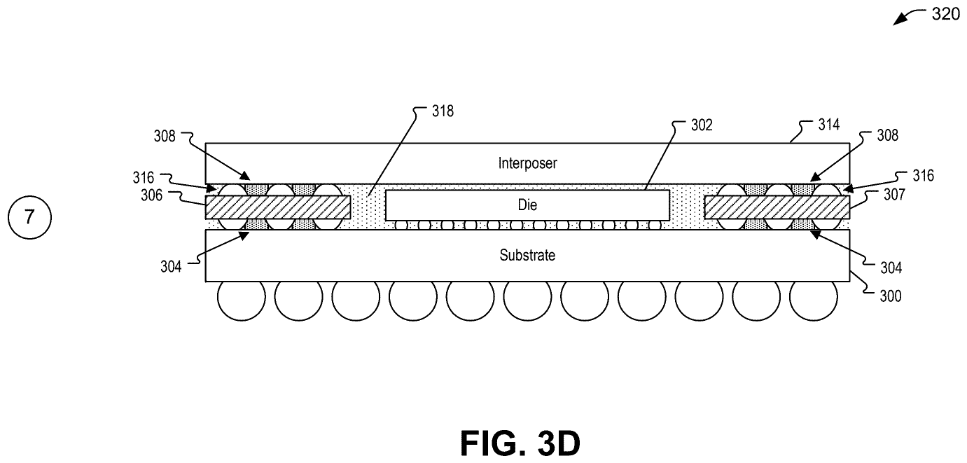

In some implementations, fabricating a device including a conductive structure and interconnects configured to electrically connect a substrate and an interposer (e.g., any of the devices 100 or 200) includes several processes. FIGS. 3A-D illustrate an exemplary sequence for fabricating or providing a device that includes a conductive structure and interconnects configured to electrically connect a substrate and an interposer, as described with reference to any of FIGS. 1A-C and 2. In some implementations, the sequence of FIGS. 3A-D may be used to provide (e.g., during fabrication of) one or more of the device 100 of FIGS. 1A-C or the device 200 of FIG. 2.

It should be noted that the sequence of FIGS. 3A-D may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 3A-D. Each of the various stages of the sequence illustrated in FIGS. 3A-D shows a single integrated device being formed. In other implementations, a plurality of integrated devices can be formed concurrently.

Stage 1 of FIG. 3A illustrates a state after a die 302 is electrically connected to a substrate 300 (e.g., a bottom substrate). For example, as part of Stage 1, the die 302 may be attached to the substrate 300 and electrically connected to the substrate 300, such as via placement of one or more terminals or other connectors of the die 302 being placed in contact with pads of the substrate 300. In some implementations, the substrate 300 includes or corresponds to the substrate 102 of FIGS. 1A-C and 2, and the die 302 includes or corresponds to the first die 104 of FIGS. 1A-C and 2. The die 302 may be attached to the substrate 300 during one or more bonding processes, such as a thermal compression bonding process or a mass reflow process. The bonding processes may include, or may be performed after, wafer receipt, bumping, die prep, or a combination thereof, on the die 302, which may be performed in parallel with, or prior to, substrate pre-bake, substrate pre-clean, organic solderability preservative (OSP) removal, or a combination thereof, on the substrate 300. Additionally, or alternatively, Stage 1 may include, or may be performed prior to, plasma cleaning, fluxing/cleaning, or a combination thereof, on the attached combination of the die 302 and the substrate 300. In some implementations, the actions described with reference to Stage 1 occur prior to any terminals for interconnects being electrically connected to the substrate 300.

Stage 2 illustrates a state after first terminals 304 are electrically connected to the substrate 300. For example, as part of Stage 2, the first terminals 304 may be attached and electrically connected to a top surface (e.g., a first surface) of the substrate 300. In some implementations, the first terminals 304 include or correspond to the first terminals 114 of FIGS. 1A-C. The first terminals 304 may be attached to the substrate 300 as part of an attachment or bonding process, that may include a paste print process performed on the substrate 300. In some implementations, the first terminals 304 may include a first set of terminals that are attached near a first end 310 of the substrate 300 (e.g., to a first side of the die 302) and a second set of terminals that are attached near a second end 312 of the substrate 300 (e.g., to a second side of the die 302 that is opposite from the first side).

Stage 3 of FIG. 3B illustrates a state after a conductive structure 306 and a conductive structure 307 are attached to the first terminals 304. For example, as part of Stage 3, the conductive structure 306 may be attached to the set of the first terminals 304 that are disposed on the first end 310 of the substrate 300, and the conductive structure 307 may be attached to the set of the first terminals 304 that are disposed on the second end 312 of the substrate 300. In some implementations, the conductive structures 306, 307 include or correspond to the conductive structures 106, 130 of FIGS. 1A-C. The conductive structures 306, 307 may be attached to the first terminals 304 via a bonding process, such as a thermal compression bonding process or another type of bonding process. Similar to as described above with reference to FIGS. 1A-C and 2, the conductive structures 306, 307 may include one or more walls that define one or more openings that are configured to receive one or more interconnects. For example, the conductive structures 306, 307 may include the walls 108 of FIGS. 1A-C that define the openings 110 of FIGS. 1A-C, as a non-limiting example. In some implementations, the conductive structures 306, 307 each include a dielectric coating that covers the respective conductive structure and provides electrical isolation between the respective conductive structure and adjacent components. In such implementations, electrically connecting the first terminals 304 to the conductive structures 306, 307 may include creating openings within the dielectric coating, such as using a lithography process, an etching process, or a grinding process, as non-limiting examples. Alternatively, in some embodiments, the dielectric coating can be omitted from or removed from bottom surfaces (in the orientation illustrated in FIG. 3B) of the conductive structures 306, 307 to facilitate electrical connection to the first terminals 304.

Stage 4 illustrates a state after second terminals 308 are electrically connected to the conductive structures 306, 307. For example, as part of Stage 4, the second terminals 308 may be attached and electrically connected to a top surface of the conductive structures 306, 307. In some implementations, the second terminals 308 include or correspond to the second terminals 112 of FIGS. 1A-C. The second terminals 308 may be attached to the conductive structures 306, 307 as part of an attachment or bonding process, which may include a paste print process performed on the conductive structures 306, 307. In some implementations, the second terminals 308 may include a third set of terminals that are attached to the conductive structure 306 and a second set of terminals that are attached to the conductive structure 307. In implementations in which the conductive structures 306, 307 include dielectric coatings, electrically connecting the second terminals 308 to the conductive structures 306, 307 may include creating openings within the dielectric coating, such as using a lithography process, an etching process, or a grinding process, as non-limiting examples. Alternatively, in some embodiments, the dielectric coating can be omitted from or removed from top surfaces (in the orientation illustrated in FIG. 3B) of the conductive structures 306, 307 to facilitate electrical connection to the second terminals 308.

Stage 5 of FIG. 3C illustrates a state after providing an interposer 314 (e.g., a top substrate) and electrically connecting interconnects 316 to the interposer 314. For example, as part of Stage 5, the interconnects 316 may be attached and electrically connected to the interposer 314. In some implementations, the interposer 314 includes or corresponds to the interposer 120 of FIGS. 1A-C and 2, and the interconnects 316 include or correspond to the interconnects 116 of FIGS. 1A-C. The interconnects 316 may be attached to the interposer 314 via a bonding process, such as a thermal compression bonding process or another type of bonding process, that is performed prior to electrically connecting the interconnects 316 to the substrate 300. In some implementations, part of Stage 5 may include pre-cleaning the interposer 314, a copper core ball attachment process (e.g., for the interposer 314 and the interconnects 316), and a top strip block singulation process. Alternatively, one or more of these operations may be performed prior to, in parallel with, or after Stage 5.

Stage 6 illustrates a state after the interconnects 316 are received within the openings defined by the walls of the conductive structures 306, 307, and the interconnects 316 are electrically connected to the substrate 300. For example, as part of Stage 6, the interposer 314 may be positioned above the substrate 300 such that the interconnects 316 are received (e.g., disposed) within the openings defined by the conductive structures 306, 307 (e.g., between adjacent walls). The interconnects 316 may be attached to the substrate 300 via a bonding process, such as a thermal compression bonding process or another type of bonding process. After Stage 6, the interconnects 316 are electrically isolated from the conductive structures 306, 307 and are electrically connected to the substrate 300, such as being in contact with pads or contacts on the top surface of the substrate 300, as non-limiting examples. Additionally, circuitry or traces of the interposer 314 and the substrate 300 may be electrically connected through the first terminals 304, the conductive structure 306, and the second terminals 308 and/or through the first terminals 304, the conductive structure 307, and the second terminals 308. In some implementations, the circuitry of the interposer 314 and the substrate 300 and the conductive structures 306, 307 may be electrically connected to a common net signal or a common source signal, such as the common ground 124 of FIGS. 1A-C or Vdd, as non-limiting examples, which may provide a nearby return path (e.g., if connected to the common ground 124) for signals that are propagated via the interconnects 316.

Stage 7 of FIG. 3D illustrates a state after a mold compound 318 is deposited between the substrate 300 and the interposer 314. For example, as part of Stage 7, a transfer molding process, or another type of mold deposition process, may be performed to deposit the mold compound 318 between the substrate 300 and the interposer 314 to at least partially encapsulate the die 302, the conductive structures 306, 307, the first terminals 304, the second terminals 308, and the interconnects 316. In some implementations, Stage 7 may include additional operations, or additional operations may be performed after Stage 7, with the additional operations including post mold curing, land side capacitor attachment, ball grid array (BGA) mounting, reflow soldering, package singulation, final testing, final visual inspecting, transferring to tape and reel, or a combination thereof.

Formation of a device 320 (e.g., a device including a conductive structure and interconnects for electrically connecting a substrate and an interposer) is complete after Stage 7 of FIG. 3D. However, in some implementations, the device 320 can be used to form the device 100 of FIGS. 1A-C or the device 200 of FIG. 2. For example, a second die, such as the second die 122, may be attached and electrically connected to the interposer 314 to form the device 100 of FIGS. 1A-C. In some implementations, the second die is a DRAM. The second die may be attached and electrically connected to the interposer 314 similar to as described for the attachment of the die 302 to the substrate 300 during Stage 1. The second die may be attached to the interposer prior to, or during, Stage 5 or after Stages 6 or 7. If the second die is attached to the interposer 314 prior to Stage 7, the transfer molding process of Stage 7 may deposit the mold compound on the second die to at least partially encapsulate the second die.

Alternatively, if the second die is attached to the interposer 314 after Stage 7, a second mold deposition process may be performed to deposit a mold compound on the second die and the interposer 314.

Although certain Stages of forming the device 320 are illustrated in FIGS. 3A-D, other processes or Stages can be included in the fabrication of the device 320 without departing from the scope of the subject disclosure. For example, fabricating the device 320 can include, instead of electrically connecting the interconnects 316 to the interposer 314 during Stage 5, depositing the interconnects 316 within the openings defined by the conductive structures 306, 307 and electrically connecting the interconnects 316 to the substrate 300. For example, the interconnects 316 may be individually disposed, or disposed as a group using a transfer technique or tool, within the openings defined by the conductive structures 306, 307, prior to being electrically connected to the interposer 314. In this example, the electrical connecting process described during Stage 6 for the interconnects 316 to the substrate 300 may be performed during Stage 5. Additionally, in this example, the interposer 314 may be positioned above the substrate 300 and electrically connected to the interconnects 316 and the second terminals 308 during Stage 6, such that the interposer 314 is electrically connected to the interconnects 316 after the interconnects 316 are electrically connected to the substrate 300.

Alternatively, the sequence described with reference to FIGS. 3A-D may be modified to form the device 200 of FIG. 2. For example, instead of attaching and electrically connecting a single conductive structure to the substrate 300 along each of the first end 310 and the second end 312 (e.g., the conductive structure 306 and the conductive structure 307, respectively) during Stage 3, fabricating the device 320 may include attaching and electrically connecting multiple discrete conductive structures to the substrate 300 along the first end 310, the second end 312, or both (e.g., to the first side of the die 302, to the second side of the die 302, or both), during Stage 3. In such implementations, multiple discrete conductive structures may be attached to the substrate 300 along the first end 310 (and/or the second end 312), with each of the conductive structures being separated by a gap to electrically isolate each of the conductive structures from adjacent conductive structures. In such implementations, the conductive structures may include or correspond to the conductive structures 202, 212, and 222 of FIG. 2, and one or more of the conductive structures may be electrically connected, via circuitry within or on different portions of the substrate 300 and the interposer 314, to different signals, such as Vdd, the common ground 124 of FIGS. 1A-C, or the like.

### Exemplary Flow Diagram of a Method for Fabricating a Device Including a Conductive Structure and Interconnects

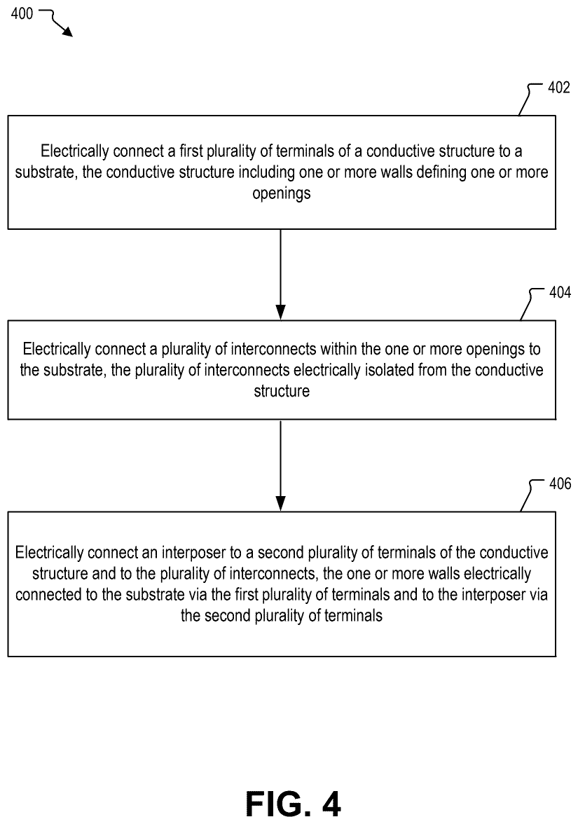

In some implementations, fabricating a device including a conductive structure and interconnects configured to electrically connect a substrate and an interposer includes several processes. FIG. 4 illustrates an exemplary flow diagram of a method 400 of fabricating an illustrative device that includes a conductive structure and interconnects configured to electrically connect a substrate and an interposer. In a particular aspect, one or more operations of the method 400 are performed by one or more processors of a fabrication system. In some implementations, operations of the method 400 may be stored as instructions by a non-transitory computer-readable storage medium, and the instructions may be executable by at least one processor to cause the at least one processor to perform operations of the method 400. In some implementations, the method 400 of FIG. 4 may be used to provide or fabricate any of the device 100 of FIGS. 1A-C, the device 200 of FIG. 2, or the device 320 of FIGS. 3A-D.

It should be noted that the method 400 of FIG. 4 may combine one or more processes in order to simplify and/or clarify the method for providing or fabricating an integrated circuit device. In some implementations, the order of the processes may be changed or modified.

The method 400 includes electrically connecting a first plurality of terminals of a conductive structure to a substrate, at block 402. The conductive structure includes one or more walls defining one or more openings. For example, Stage 2 of FIG. 3A illustrates and describes examples of electrically connecting the first terminals 304 to the substrate 300. The first plurality of terminals of the method 400 can include the first terminals 114 of FIGS. 1A-C or the first terminals 304 of FIGS. 3A-D, the substrate of the method 400 can include the substrate 102 of FIGS. 1A-C and 2 or the substrate 300 of FIGS. 3A-D, and the conductive structure of the method 400 can include the conductive structure 106 of FIGS. 1A-C, the conductive structure 202 of FIG. 2, or the conductive structure 306 of FIGS. 3A-D. The one or more walls of the conductive structure of the method 400 can include the walls 108 of FIGS. 1A-C or the walls 204 of FIG. 2, and the one or more openings of the method 400 can include the openings 110 of FIGS. 1A-C or the openings 206 of FIG. 2.

The method 400 includes electrically connecting a plurality of interconnects within the one or more openings to the substrate, at block 404. The plurality of interconnects are electrically isolated from the conductive structure. For example, Stage 6 of FIG. 3C illustrates and describes examples of electrically connecting the interconnects 316 to the substrate 300, with the interconnects 316 being positioned in openings such that they are electrically isolated from the conductive structures 306, 307. The plurality of interconnects of the method 400 can include the interconnects 116 of FIGS. 1A-C, the interconnects 210 of FIG. 2, or the interconnects 316 of FIGS. 3A-D.

The method 400 includes electrically connecting an interposer to a second plurality of terminals of the conductive structure and to the plurality of interconnects, at block 406. The one or more walls are electrically connected to the substrate via the first plurality of terminals and to the interposer via the second plurality of terminals. For example, Stage 4 of FIG. 3B illustrates and describes examples of electrically connecting the second terminals 308 to the conductive structures 306, 307, and Stage 6 of FIG. 3C illustrates and describes examples of electrically connecting the interposer 314 to the second terminals 308. Additionally, Stage 5 of FIG. 3C illustrates and describes examples of electrically connecting the interposer 314 to the interconnects 316. The interposer of the method 400 can include the interposer 120 of FIGS. 1A-C or the interposer 314 of FIGS. 3A-D, and the second plurality of terminals of the method 400 can include the second terminals 112 of FIGS. 1A-C, the second terminals 208 of FIG. 2, or the second terminals 308 of FIGS. 3A-D.

In some implementations, the method 400 further includes depositing a mold compound between the substrate and the interposer. The mold compound at least partially encapsulates the conductive structure. For example, Stage 7 of FIG. 3D illustrates and describes examples of depositing the mold compound 318 between the substrate 300 and the interposer 314. The mold compound of the method 400 can include the mold compound 318 of FIGS. 3A-D.

In some implementations, the method 400 also includes, prior to electrically connecting the first plurality of terminals to the substrate, electrically connecting a first die to the substrate. In such implementations, the method 400 further includes, after electrically connecting the interposer to the second plurality of terminals and to the plurality of interconnects, electrically connecting a second die to the interposer. The second die includes a DRAM. For example, Stage 1 of FIG. 3A illustrates and describes examples of electrically connecting the die 302 to the substrate 300. The first die of the method 400 can include the first die 104 of FIGS. 1A-C and 2 or the die 302 of FIGS. 3A-D. The second die of the method 400 can include the second die 122 of FIGS. 1A-C, which may include a DRAM.

In some implementations, the method 400 also includes, prior to electrically connecting the plurality of interconnects to the substrate, electrically connecting the plurality of interconnects to the interposer and positioning the interposer such that the plurality of interconnects are disposed within the one or more openings to electrically connect the plurality of interconnects to the substrate. For example, Stage 5 of FIG. 3C illustrates and describes examples of electrically connecting the interconnects 316 to the interposer 314, and Stage 6 of FIG. 3C illustrates and describes examples of positioning the interposer 314 such that the interconnects are disposed within openings defined by walls of the conductive structures 306, 307.

In some implementations, the method 400 also includes electrically connecting a third plurality of terminals of a second conductive structure to the substrate. The second conductive structure includes one or more additional walls defining one or more additional openings, and the conductive structure is electrically isolated from the second conductive structure. For example, Stage 3 of FIG. 3B illustrates and describes examples of electrically connecting the conductive structure 306 to the substrate 300 and electrically connecting the conductive structure 307 to the substrate 300 such that the conductive structure 306 can be electrically isolated from the conductive structure 307. The second conductive structure of the method 400 can include the conductive structure 130 of FIGS. 1A-C, the conductive structure 212 or 222 of FIG. 2, or the conductive structure 307 of FIGS. 3A-D. In such implementations, the method 400 also includes electrically connecting a second plurality of interconnects within the one or more additional openings of the second conductive structure to the substrate. The second plurality of interconnects are electrically isolated from the second conductive structure. For example, Stage 6 of FIG. 3C illustrates and describes examples of electrically connecting the interconnects 316 to the substrate 300 within openings defined by the walls of the conductive structure 307. The second plurality of interconnects of the method 400 can include some of the interconnects 116 of FIGS. 1A-C, the interconnects 220 or 230 of FIG. 2, or some of the interconnects 316 of FIGS. 3A-D.

In implementations in which the method 400 includes electrically connecting the second plurality of interconnects to the substrate, the method 400 also includes electrically connecting the interposer to a fourth plurality of terminals of the second conductive structure and to the second plurality of interconnects. The one or more additional walls of the second conductive structure are electrically connected to the substrate via the third plurality of terminals and to the interposer via the fourth plurality of terminals. For example, Stage 4 of FIG. 3B illustrates and describes examples of electrically connecting the second terminals 308 to the conductive structure 307, and Stage 6 of FIG. 3C illustrates and describes examples of electrically connecting the interposer 314 to the second terminals 308. Additionally, Stage 3 of FIG. 3B illustrates and describes examples of electrically connecting the conductive structure 307 to the first terminals 304. The third plurality of terminals of the method 400 can include some of the first terminals 114 of FIGS. 1A-C or some of the first terminals 304 of FIGS. 3A-D, and the fourth plurality of terminals of the method 400 can include some of the second terminals 112 of FIGS. 1A-C, the fourth terminals 218 or the sixth terminals 228 of FIG. 2, or some of the second terminals 308 of FIGS. 3A-D.

### Exemplary Electronic Devices

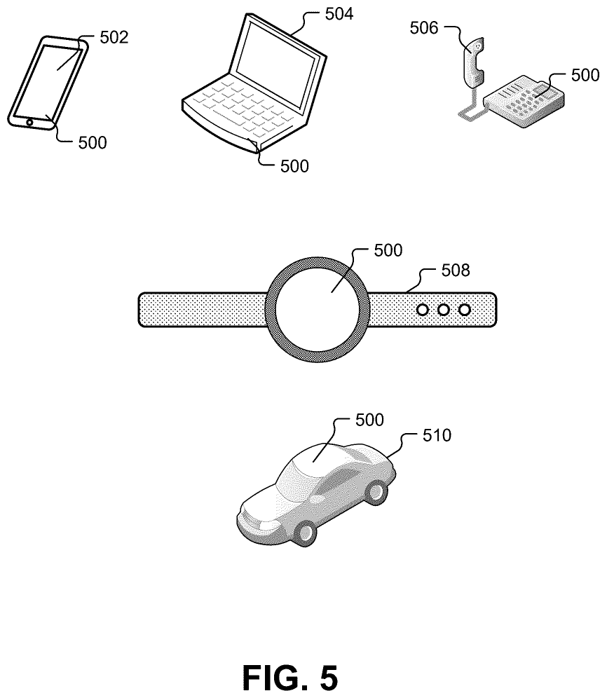

FIG. 5 illustrates various electronic devices that may include or be integrated with any of the device 100 (that includes a conductive structure and interconnects configured to electrically connect a substrate and an interposer), the device 200, or the device 320. For example, a mobile phone device 502, a laptop computer device 504, a fixed location terminal device 506, a wearable device 508, or a vehicle 510 (e.g., an automobile or an aerial device) may include a device 500. The device 500 can include, for example, any of the device 100, the device 200, the device 320, and/or any other integrated device that includes a conductive structure and interconnects described herein. The devices 502, 504, 506 and 508 and the vehicle 510 illustrated in FIG. 5 are merely exemplary. Other electronic devices may also feature the device 500 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1A-C, 2, 3A-D, 4, and 5 may be rearranged and/or combined into a single component, process, feature or function or embodied in several components, processes, or functions. Additional elements, components, processes, and/or functions may also be added without departing from the disclosure. It should also be noted FIGS. 1A-C, 2, 3A-D, 4, and 5 and their corresponding description in the present disclosure is not limited to dies and/or ICs. In some implementations, FIGS. 1A-C, 2, 3A-D, 4, and 5 and their corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a substrate; an interposer; a die disposed between the substrate and the interposer; a conductive structure disposed between the substrate and the interposer, the conductive structure including one or more walls defining one or more openings, the one or more walls electrically connected to the substrate via a first plurality of terminals and to the interposer via a second plurality of terminals; and a plurality of interconnects disposed within the one or more openings and electrically isolated from the conductive structure, the plurality of interconnects electrically connecting the substrate and the interposer.

Example 2 includes the device of Example 1, wherein the conductive structure includes a metal or a metal alloy having a dielectric coating.

Example 3 includes the device of Example 1 or Example 2, wherein one or more gaps separate each of the plurality of interconnects from physical contact with the one or more walls.

Example 4 includes the device of any of Examples 1 to 3, wherein the conductive structure is electrically connected to a common ground via the substrate and the interposer.

Example 5 includes the device of any of Examples 1 to 4, wherein the conductive structure is electrically connected to a common source voltage via the substrate and the interposer.

Example 6 includes the device of any of Examples 1 to 5, wherein: the plurality of interconnects includes a plurality of sets of interconnects; each opening of the one or more openings is separated from an adjacent opening of the one or more openings by one of the one or more walls; and each set of interconnects of the plurality of sets of interconnects is disposed within a corresponding opening of the one or more openings.

Example 7 includes the device of Example 6, wherein: a first wall of the one or more walls separates a first opening of the one or more openings from a second opening of the one or more openings; a first set of interconnects is disposed within the first opening; a second set of interconnects is disposed within the second opening; a first subset of the first plurality of terminals is disposed on a first surface of the first wall; and a second subset of the second plurality of terminals is disposed on a second surface of the first wall, the second surface opposite to the first surface.

Example 8 includes the device of any of Examples 1 to 7, further including: a second conductive structure disposed between the substrate and the interposer, the second conductive structure including one or more additional walls defining one or more additional openings, the one or more additional walls electrically connected to the substrate via a third plurality of terminals and to the interposer via a fourth plurality of terminals; and a second plurality of interconnects disposed within the one or more additional openings and electrically isolated from the second conductive structure.

Example 9 includes the device of Example 8, wherein the conductive structure is electrically connected to a first reference voltage via one or more conductors associated with a first portion of the substrate and one or more conductors associated with a first portion of the interposer, and wherein the second conductive structure is electrically connected to a second reference voltage that is different than the first reference voltage via one or more conductors associated with a second portion of the substrate and one or more conductors associated with a second portion of the interposer.

Example 10 includes the device of any of Example 8 or Example 9, wherein the conductive structure and the plurality of interconnects are disposed on a first end of the die, and wherein the second conductive structure and the second plurality of interconnects are disposed on a second end of the die that is opposite to the first end.

According to Example 11 a method of semiconductor fabrication includes: electrically connecting a first plurality of terminals of a conductive structure to a substrate, the conductive structure including one or more walls defining one or more openings; electrically connecting a plurality of interconnects within the one or more openings to the substrate, the plurality of interconnects electrically isolated from the conductive structure; and electrically connecting an interposer to a second plurality of terminals of the conductive structure and to the plurality of interconnects, the one or more walls electrically connected to the substrate via the first plurality of terminals and to the interposer via the second plurality of terminals.

Example 12 includes the method of Example 11, further including: prior to electrically connecting the first plurality of terminals to the substrate, electrically connecting a first die to the substrate; and after electrically connecting the interposer to the second plurality of terminals and to the plurality of interconnects, electrically connecting a second die to the interposer, the second die including a dynamic random-access memory (DRAM).

Example 13 includes the method of Example 11 or Example 12, further including depositing a mold compound between the substrate and the interposer, wherein the mold compound at least partially encapsulates the conductive structure.

Example 14 includes the method of any of Examples 11 to 13, further including: prior to electrically connecting the plurality of interconnects to the substrate, electrically connecting the plurality of interconnects to the interposer; and positioning the interposer such that the plurality of interconnects are disposed within the one or more openings to electrically connect the plurality of interconnects to the substrate.

Example 15 includes the method of any of Examples 11 to 14, further including: electrically connecting a third plurality of terminals of a second conductive structure to the substrate, the second conductive structure including one or more additional walls defining one or more additional openings, wherein the conductive structure is electrically isolated from the second conductive structure; electrically connecting a second plurality of interconnects within the one or more additional openings of the second conductive structure to the substrate, the second plurality of interconnects electrically isolated from the second conductive structure; and electrically connecting the interposer to a fourth plurality of terminals of the second conductive structure and to the second plurality of interconnects, the one or more additional walls of the second conductive structure electrically connected to the substrate via the third plurality of terminals and to the interposer via the fourth plurality of terminals.

According to Example 16, a device includes a conductive structure configured to provide common voltage interconnections between a substrate and an interposer, the conductive structure including: one or more walls defining one or more openings configured to receive a plurality of interconnects between the substrate and the interposer, the one or more walls electrically isolated from the plurality of interconnects; a first plurality of terminals configured to provide electrical interconnections to the substrate; and a second plurality of terminals configured to provide electrical interconnections to the interposer.

Example 17 includes the device of Example 16, wherein the conductive structure includes a metal or a metal alloy having a dielectric coating.

Example 18 includes the device of Example 16 or Example 17, wherein a sum of a height of a first terminal of the first plurality of terminals, a height of a second terminal of the second plurality of terminals, and a height of a first wall of the one or more walls that is disposed between the first terminal and the second terminal is substantially equal to a height of a first interconnect of the plurality of interconnects.

Example 19 includes the device of any of Examples 16 to 18, wherein: the one or more walls include a first wall and a second wall that extends parallel to the first wall; the plurality of interconnects includes a first set of interconnects; and a first opening of the one or more openings between the first wall and the second wall is configured to receive the first set of interconnects.

Example 20 includes the device of Example 19, wherein: the one or more walls further include a third wall; the first wall and the third wall include outer walls of the conductive structure and the second wall includes an inner wall of the conductive structure; the plurality of interconnects includes a second set of interconnects; and a second opening of the one or more openings between the second wall and the third wall is configured to receive the second set of interconnects.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
a substrate;
an interposer;
a die disposed between the substrate and the interposer;
a conductive structure disposed between the substrate and the interposer, the conductive structure comprising one or more walls defining one or more openings, the one or more walls electrically connected to the substrate via a first plurality of terminals and to the interposer via a second plurality of terminals; and
a plurality of interconnects disposed within the one or more openings and electrically isolated from the conductive structure, the plurality of interconnects electrically connecting the substrate and the interposer.

2. The device of claim 1, wherein the conductive structure comprises a metal or a metal alloy having a dielectric coating.

3. The device of claim 1, wherein one or more gaps separate each of the plurality of interconnects from physical contact with the one or more walls.

4. The device of claim 1, wherein the conductive structure is electrically connected to a common ground via the substrate and the interposer.

5. The device of claim 1, wherein the conductive structure is electrically connected to a common source voltage via the substrate and the interposer.

6. The device of claim 1, wherein:
the plurality of interconnects comprises a plurality of sets of interconnects;
each opening of the one or more openings is separated from an adjacent opening of the one or more openings by one of the one or more walls; and
each set of interconnects of the plurality of sets of interconnects is disposed within a corresponding opening of the one or more openings.

7. The device of claim 6, wherein:
a first wall of the one or more walls separates a first opening of the one or more openings from a second opening of the one or more openings;
a first set of interconnects is disposed within the first opening;
a second set of interconnects is disposed within the second opening;
a first subset of the first plurality of terminals is disposed on a first surface of the first wall; and
a second subset of the second plurality of terminals is disposed on a second surface of the first wall, the second surface opposite to the first surface.

8. The device of claim 1, further comprising:
a second conductive structure disposed between the substrate and the interposer, the second conductive structure comprising one or more additional walls defining one or more additional openings, the one or more additional walls electrically connected to the substrate via a third plurality of terminals and to the interposer via a fourth plurality of terminals; and
a second plurality of interconnects disposed within the one or more additional openings and electrically isolated from the second conductive structure.

9. The device of claim 8, wherein the conductive structure is electrically connected to a first reference voltage via one or more conductors associated with a first portion of the substrate and one or more conductors associated with a first portion of the interposer, and wherein the second conductive structure is electrically connected to a second reference voltage that is different than the first reference voltage via one or more conductors associated with a second portion of the substrate and one or more conductors associated with a second portion of the interposer.

10. The device of claim 8, wherein the conductive structure and the plurality of interconnects are disposed on a first end of the die, and wherein the second conductive structure and the second plurality of interconnects are disposed on a second end of the die that is opposite to the first end.

11. A method of semiconductor fabrication, the method comprising:
electrically connecting a first plurality of terminals of a conductive structure to a substrate, the conductive structure comprising one or more walls defining one or more openings;
electrically connecting a plurality of interconnects within the one or more openings to the substrate, the plurality of interconnects electrically isolated from the conductive structure; and
electrically connecting an interposer to a second plurality of terminals of the conductive structure and to the plurality of interconnects, the one or more walls electrically connected to the substrate via the first plurality of terminals and to the interposer via the second plurality of terminals.

12. The method of claim 11, further comprising:
prior to electrically connecting the first plurality of terminals to the substrate, electrically connecting a first die to the substrate; and
after electrically connecting the interposer to the second plurality of terminals and to the plurality of interconnects, electrically connecting a second die to the interposer, the second die comprising a dynamic random-access memory (DRAM).

13. The method of claim 11, further comprising depositing a mold compound between the substrate and the interposer, wherein the mold compound at least partially encapsulates the conductive structure.

14. The method of claim 11, further comprising:
prior to electrically connecting the plurality of interconnects to the substrate, electrically connecting the plurality of interconnects to the interposer; and
positioning the interposer such that the plurality of interconnects are disposed within the one or more openings to electrically connect the plurality of interconnects to the substrate.

15. The method of claim 11, further comprising:
electrically connecting a third plurality of terminals of a second conductive structure to the substrate, the second conductive structure comprising one or more additional walls defining one or more additional openings, wherein the conductive structure is electrically isolated from the second conductive structure;
electrically connecting a second plurality of interconnects within the one or more additional openings of the second conductive structure to the substrate, the second plurality of interconnects electrically isolated from the second conductive structure; and
electrically connecting the interposer to a fourth plurality of terminals of the second conductive structure and to the second plurality of interconnects, the one or more additional walls of the second conductive structure electrically connected to the substrate via the third plurality of terminals and to the interposer via the fourth plurality of terminals.

16. A device comprising:
a conductive structure configured to provide common voltage interconnections between a substrate and an interposer, the conductive structure comprising:
one or more walls defining one or more openings configured to receive a plurality of interconnects between the substrate and the interposer, the one or more walls electrically isolated from the plurality of interconnects;
a first plurality of terminals configured to provide electrical interconnections to the substrate; and
a second plurality of terminals configured to provide electrical interconnections to the interposer.

17. The device of claim 16, wherein the conductive structure comprises a metal or a metal alloy having a dielectric coating.

18. The device of claim 16, wherein a sum of a height of a first terminal of the first plurality of terminals, a height of a second terminal of the second plurality of terminals, and a height of a first wall of the one or more walls that is disposed between the first terminal and the second terminal is substantially equal to a height of a first interconnect of the plurality of interconnects.

19. The device of claim 16, wherein:
the one or more walls comprise a first wall and a second wall that extends parallel to the first wall;
the plurality of interconnects comprises a first set of interconnects; and
a first opening of the one or more openings between the first wall and the second wall is configured to receive the first set of interconnects.

20. The device of claim 19, wherein:
the one or more walls further comprise a third wall;
the first wall and the third wall comprise outer walls of the conductive structure and the second wall comprises an inner wall of the conductive structure;
the plurality of interconnects comprises a second set of interconnects; and
a second opening of the one or more openings between the second wall and the third wall is configured to receive the second set of interconnects.
